(19) United States
(12) Patent Application Publication
(10) Pub. No.: US 2013/0153391 A1
(43) Pub. Date: Jun. 20, 2013

(54) CAPACITIVE TOUCH PANEL

(71) Applicants: Wintek (China) Technology Ltd., Dongguan City (CN); Wintek Corporation, Taichung City (TW)

(72) Inventors: Chin-Chang Liu, Taichung City (TW); Kuo-Chang Su, Taichung City (TW); Wen-Chun Wang, Taichung City (TW)

(73) Assignees: WINTEK CORPORATION, Taichung City (TW); WINTEK (CHINA) TECHNOLOGY LTD., Dongguan City (CN)

(21) Appl. No.: 13/714,330

(22) Filed: Dec. 13, 2012

(30) Foreign Application Priority Data
Dec. 14, 2011 (TW) 100146153

(51) Int. Cl. H03K 17/96

(52) U.S. Cl. CPC H03K 17/9622
USPC 200/600

(57) ABSTRACT

A capacitive touch panel includes a substrate, a plurality of first axis electrodes and a plurality of second axis electrodes disposed on the substrate. Each of the first axis electrodes includes a plurality of first sensing electrodes disposed along a first direction and a plurality of first connecting electrodes respectively disposed between two adjacent first sensing electrodes. Each of the second axis electrodes includes a plurality of second sensing electrodes disposed along a second direction and a plurality of second connecting electrodes respectively disposed between two adjacent second sensing electrodes. Each of the first sensing electrodes partially overlaps the second sensing electrodes along a third direction perpendicular to the substrate.

### BACKGROUND OF THE INVENTION

1. Field of the Invention

The present invention relates to a capacitive touch panel, and more particularly, to a capacitive touch panel where each of the sensing electrodes disposed on an axis along a direction partially overlaps the sensing electrodes disposed on an axis along another direction.

2. Description of the Prior Art

In the conventional capacitive touch panel technology, the transparent sensing electrodes are commonly made of indium tin oxide (ITO), and the structures of the capacitive touch panels can be categorized as single-sided ITO (SITO) or double-sided ITO (DITO) according to the disposition of transparent sensing electrodes. In the SITO structure, diamond-shaped sensing pads are used as sensing electrodes. On an axis along a direction, each of the sensing electrodes can be connected by the connecting electrodes having a width smaller than a width of the sensing electrode, and the sensing electrodes do not overlap each other. Furthermore, the position of the touch point is determined by detecting the horizontal capacitance changes between each of the sensing electrodes. Accordingly, if the sensing electrodes on the two axis respectively along different directions are used to overlap each other to form a vertical capacitance, a too huge capacitance may be induced in the SITO structure due to the limitation of the dielectric layer thickness in the range from a few micrometers to tens of micrometers, and a fluctuation of the overlapping region between the sensing electrodes may occur due to process deviation. On the other hand, in the DITO structure, a substrate having a thickness around 100 micrometers is disposed between the sensing electrodes respectively on the two axis along different directions, so that diamond-shaped sensing electrodes can not be used because of an insufficient horizontal capacitance, and problems of fluctuant overlapping regions between the sensing electrodes may occur as well. Therefore, to obtain the stability of the overlapping region along the vertical direction, the electrodes having stripe patterns are usually disposed perpendicularly to each other in the conventional capacitive touch panel having DITO structures. However, the design change of the electrodes having stripe patterns may affect the overall resistance of the electrodes on each of the axis along a direction, for example, a width of electrodes is reduced to decrease the vertical overlapping region, and the shrunken width of the electrodes may increase the overall resistance of electrodes on the same axis. Consequently, the utilization of electrodes having stripe patterns may restrict the adjustment of the capacitive touch panel design.

### SUMMARY OF THE INVENTION

An objective of the present invention is therefore to provide a capacitive touch panel. The change of the patterns of the sensing electrodes can improve the stability of the vertical capacitance formed by the overlapped sensing electrodes.

According to one exemplary embodiment of the present invention, a capacitive touch panel is provided. The capacitive touch panel includes a substrate, a plurality of first axis electrodes and a plurality of second axis electrodes. The substrate has a first surface and a second surface. The first axis electrodes are disposed on the substrate, and each of the first axis electrodes extends along a first direction. Each of the first axis electrodes includes a plurality of first sensing electrodes disposed along the first direction and a plurality of first connecting electrodes respectively disposed between two adjacent first sensing electrodes, and the first sensing electrodes are electrically connected by the first connecting electrodes in the same first axis electrode. The second axis electrodes are disposed on the substrate, and each of the second axis electrodes extends along a second direction. Each of the second axis electrodes includes a plurality of second sensing electrodes disposed along the second direction and a plurality of second connecting electrodes that are respectively disposed between two adjacent second sensing electrodes, and the second sensing electrodes are electrically connected by the second connecting electrodes in the same second axis electrode. A width of each of the first connecting electrodes is substantially smaller than a width of each of the first sensing electrodes along the second direction, a width of each of the second connecting electrodes is substantially smaller than a width of each of the second sensing electrodes along the first direction, and each of the first sensing electrodes partially overlaps the second sensing electrodes along a third direction perpendicular to the substrate.

In the present invention, the change of pattern design of each of the sensing electrodes can reduce the effect caused by the fluctuation of the overlapping region between the sensing electrodes along the vertical direction due to the process deviation. Furthermore, the region wherein the sensing electrodes overlap each other can be modified to optimize the vertical capacitance as predetermined without affecting the overall resistance of each of the axis electrodes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view illustrating a capacitive touch panel according to the first exemplary embodiment of the present invention.

FIG. 2 is a cross-sectional view taken along the line A-A′ of FIG. 1.

FIG. 3, FIG. 4 and FIG. 5 are top views illustrating a capacitive touch panel according to the first exemplary embodiment of the present invention.

FIG. 6 is a cross-sectional view illustrating a capacitive touch panel according to the second exemplary embodiment of the present invention.

FIG. 7, FIG. 8 and FIG. 9 are top views illustrating a capacitive touch panel according to the third exemplary embodiment of the present invention.

FIG. 10 is a top view illustrating a capacitive touch panel according to the fourth exemplary embodiment of the present invention.

FIG. 11, FIG. 12 and FIG. 13 are top views illustrating a capacitive touch panel according to the fifth exemplary embodiment of the present invention.

FIG. 14 is a top view illustrating a capacitive touch panel according to the sixth exemplary embodiment of the present invention.

FIG. 15 is a cross-sectional view taken along the line B-B′ of FIG. 14.

### DETAILED DESCRIPTION

To provide a better understanding of the present invention, preferred exemplary embodiments will be described in detail herein. The preferred exemplary embodiments of the present invention are illustrated in the accompanying drawings with numbered elements.

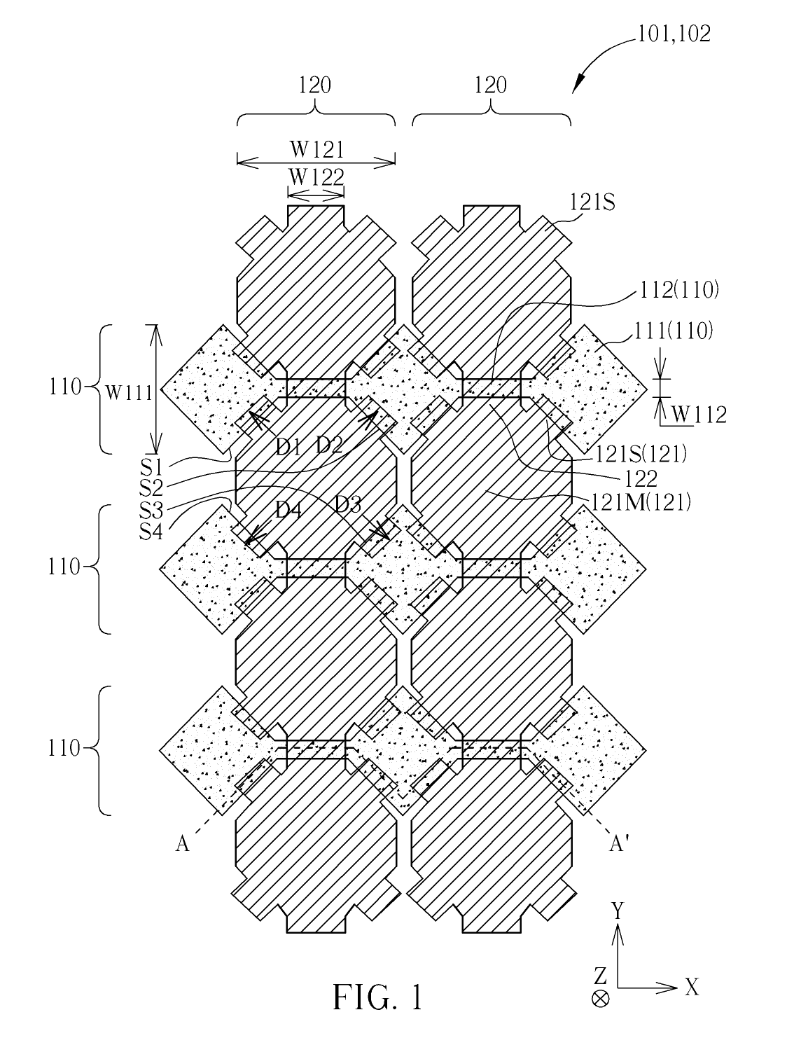

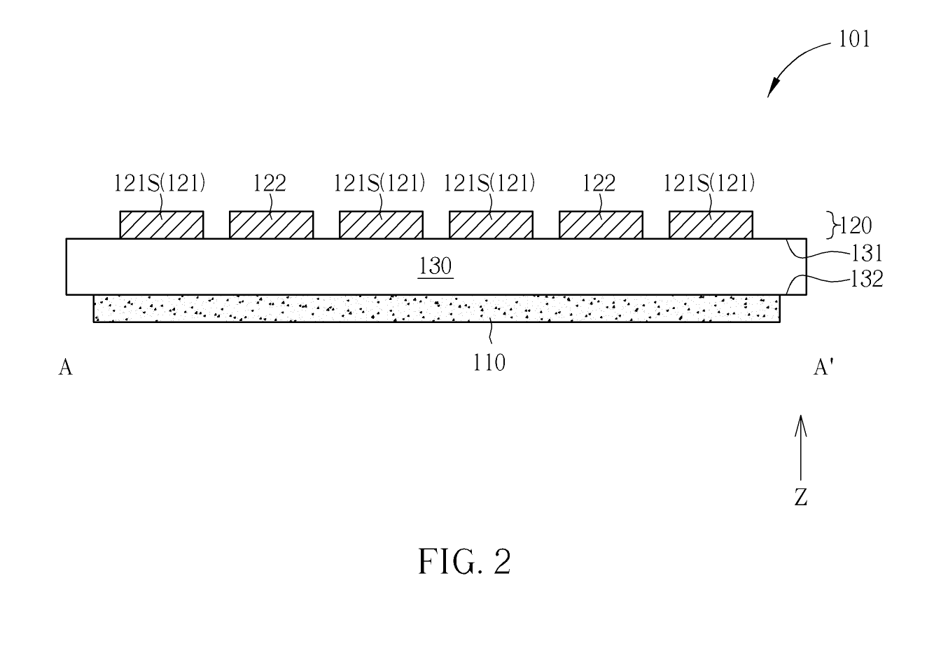

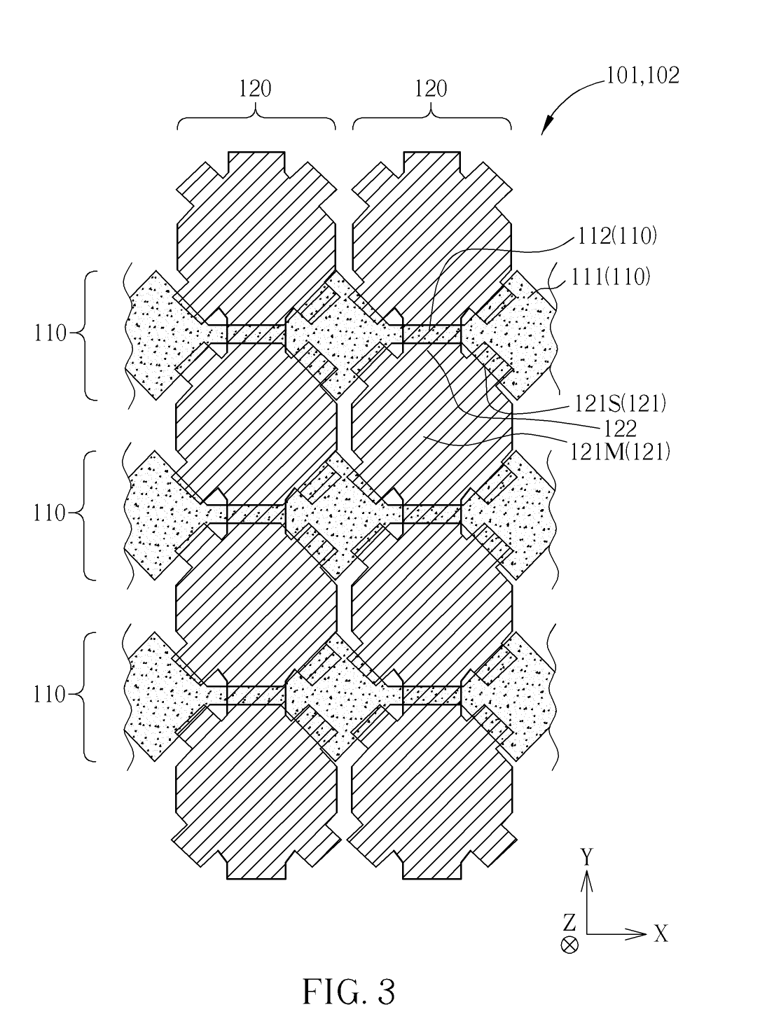

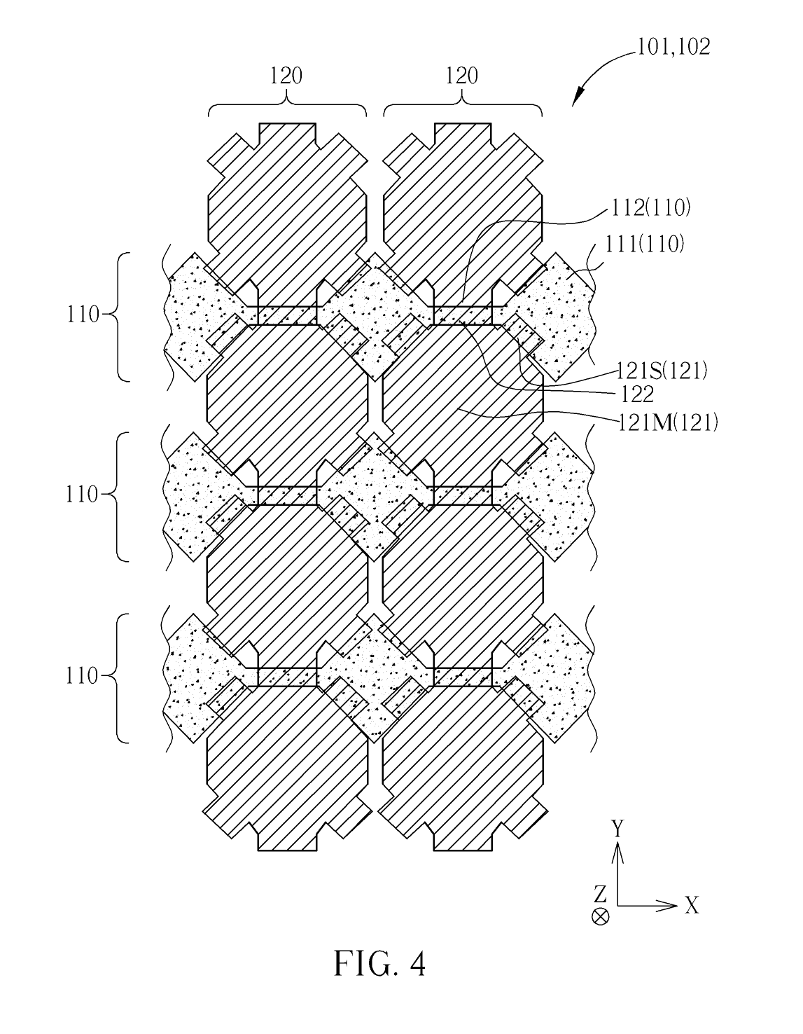

As shown in FIG. 1 and FIG. 2, in the first exemplary embodiment, the capacitive touch panel 101 includes a substrate 130, a plurality of first axis electrodes 110 and a plurality of second axis electrodes 120. The substrate 130 has a first surface 131 and a second surface 132. The first axis electrodes 110 are disposed on the second surface 132 of the substrate 130, and each of the first axis electrodes 110 extends along a first direction X. Each of the first axis electrodes 110 includes a plurality of first sensing electrodes 111 disposed along the first direction X and a plurality of first connecting electrodes 112 respectively disposed between two adjacent first sensing electrodes 111, and the first sensing electrodes 111 are electrically connected by the first connecting electrodes 112 in the same first axis electrode 110. The second axis electrodes 120 are disposed on the first surface 131 of the substrate 130, and each of the second axis electrodes 120 extends along a second direction Y. Each of the second axis electrodes 120 includes a plurality of second sensing electrodes 121 disposed along the second direction Y and a plurality of second connecting electrodes 122 respectively disposed between two adjacent second sensing electrodes 121, and the second sensing electrodes 121 are electrically connected by the second connecting electrodes 122 in the same second axis electrode 120. Furthermore, a width W112 of each of the first connecting electrodes 112 is substantially smaller than a width W111 of each of the first sensing electrodes 111 along the second direction Y, a width W122 of each of the second connecting electrodes 122 is substantially smaller than a width W121 of each of the second sensing electrodes 121 along the first direction X, and each of the first sensing electrodes 111 partially overlaps the second sensing electrodes 121 along a third direction Z perpendicular to the substrate 130. In this exemplary embodiment, the substrate 130 is disposed between the first axis electrode 110 and the second axis electrode 120, and vertical capacitance may be formed by the region of the substrate 130 wherein each of the first sensing electrodes 111 partially overlaps each of the second sensing electrodes 121 along the third direction Z. The substrate 130 of this exemplary embodiment may include hard substrate such as glass substrate or ceramic substrate, or flexible substrate such as plastic substrate or substrate made of other proper materials.

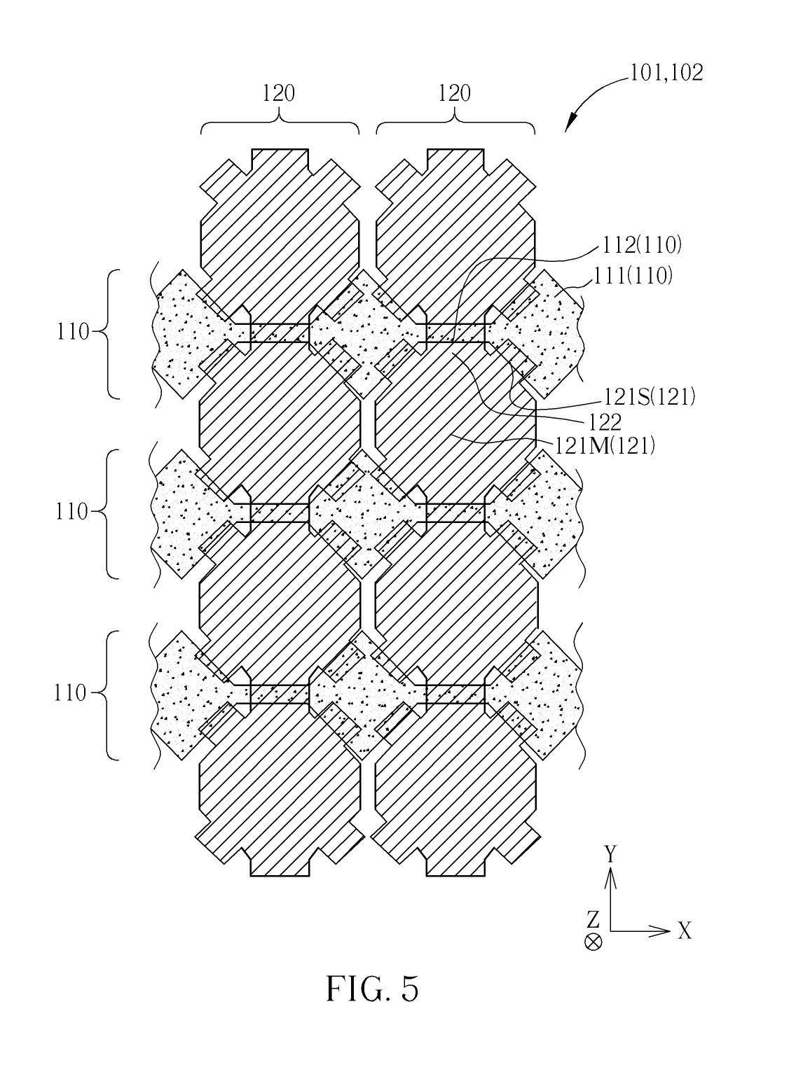

As shown in FIG. 1, in this exemplary embodiment, each of the second sensing electrodes 121 may include a main electrode 121M and a plurality of extending electrodes 121S electrically connected to the main electrode 121M. Each of the first sensing electrodes 111 at least partially overlaps the extending electrodes 121S along the third direction Z. Each of the extending electrodes 121S respectively has an extending direction D1, an extending direction D2, an extending direction D3 and an extending direction D4. The extending direction D1, the extending direction D2, the extending direction D3 and the extending direction D4 are respectively perpendicular to a side S1, a side S2, a side S3 and a side S4 of the first sensing electrode 111. The illustrated pattern design of the second sensing electrodes 121 can maintain the sum of the regions where each of the first sensing electrodes 111 partially overlaps each of the second sensing electrodes 121 along the third direction Z without being affected by the shift of the relative position of each of the first axis electrodes 110 and each of the second axis electrodes 120. More specifically, as shown in FIG. 3 through FIG. 5, in this exemplary embodiment, each of the second axis electrodes 120 shifts toward the first direction X as shown in FIG. 3, each of the second axis electrodes 120 shifts toward the second direction Y as shown in FIG. 4, and each of the second axis electrodes 120 shifts simultaneously toward the first direction X and the second direction Y as shown in FIG. 5. The sum of the regions wherein each of the first sensing electrodes 111 partially overlaps each of the second sensing electrodes 121 along the third direction Z may be kept at a fixed value due to the complementary effect, and will therefore not be affected by the shift of the relative position of each of the first axis electrodes 110 and each of the second axis electrodes 120. Accordingly, the value of the vertical capacitance can be stabilized. Furthermore, the regions wherein each of the sensing electrodes partially overlaps each other can be modified without affecting the overall resistance of each of the axis electrodes to optimize the vertical capacitance. In this exemplary embodiment, the material of each of the first axis electrodes 110 and each of the second axis electrodes 120 may include transparent conductive material such as indium tin oxide (ITO), indium zinc oxide (IZO), aluminum zinc oxide (AZO), or opaque conductive material such as silver (Ag), aluminum (Al), copper (Cu), magnesium (Mg), a composite layer made of the illustrated materials, or an alloy made of the illustrated materials. It is appreciated that each of the first axis electrodes 110 and each of the second axis electrodes 120 could be made of the same material to simplify the manufacturing process, but not limited thereto. Each of the first sensing electrodes 111, each of the first connecting electrodes 112, each of the second sensing electrodes 121 and each of the second connecting electrodes 122 could be respectively made of different materials.

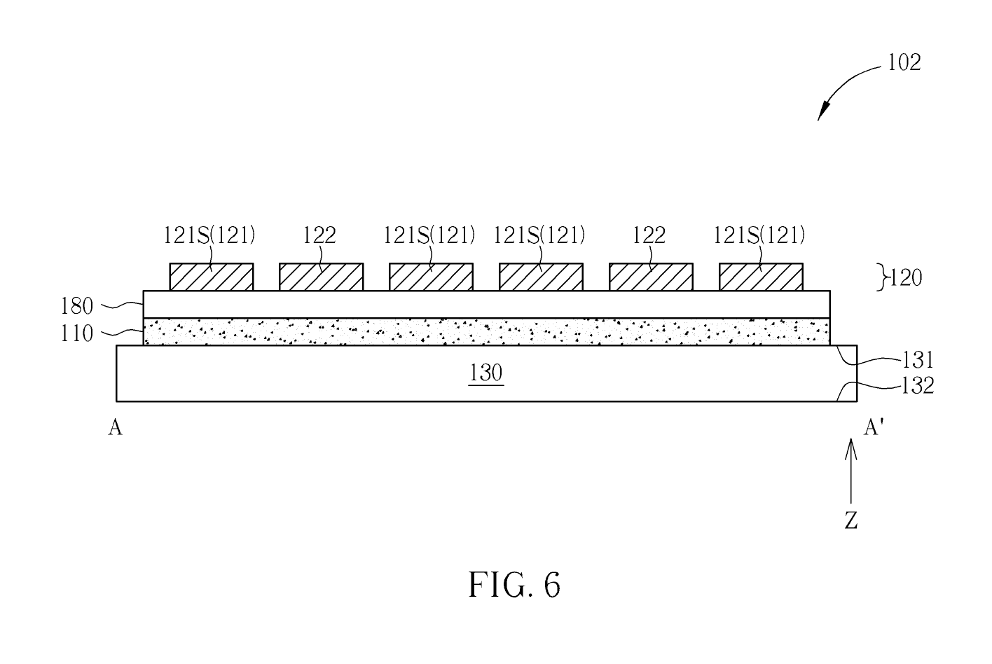

As shown in FIG. 6 and FIG. 1, compared to the capacitive touch panel 101, in the capacitive touch panel 102, the first axis electrodes 110 and the second axis electrodes 120 are disposed on the first surface 131 of the substrate 130. The capacitive touch panel 102 further includes a dielectric layer 180 disposed on the first surface 131 of the substrate 130, and the dielectric layer 180 is disposed between the first axis electrode 110 and the second axis electrode 120. In this exemplary embodiment, as the dielectric layer 180 is disposed between the first axis electrode 110 and the second axis electrode 120, the vertical capacitance may be formed by the region of the dielectric layer 180 wherein each of the first sensing electrodes 111 partially overlaps each of the second sensing electrodes 121 along the third direction Z. The material of the dielectric layer 180 may include inorganic material such as silicon nitride, silicon oxide or silicon oxynitride, or organic material such as acrylic resin or other proper materials. In this exemplary embodiment, the characteristics and the materials of the other components of the capacitive touch panel 102 are the same as the capacitive touch panel 101 of the first exemplary embodiment, except for the dielectric layer 180 and the disposition of each of the first axis electrodes 110 and each of the second axis electrodes 120, therefore, the similarities are omitted herein for brevity.

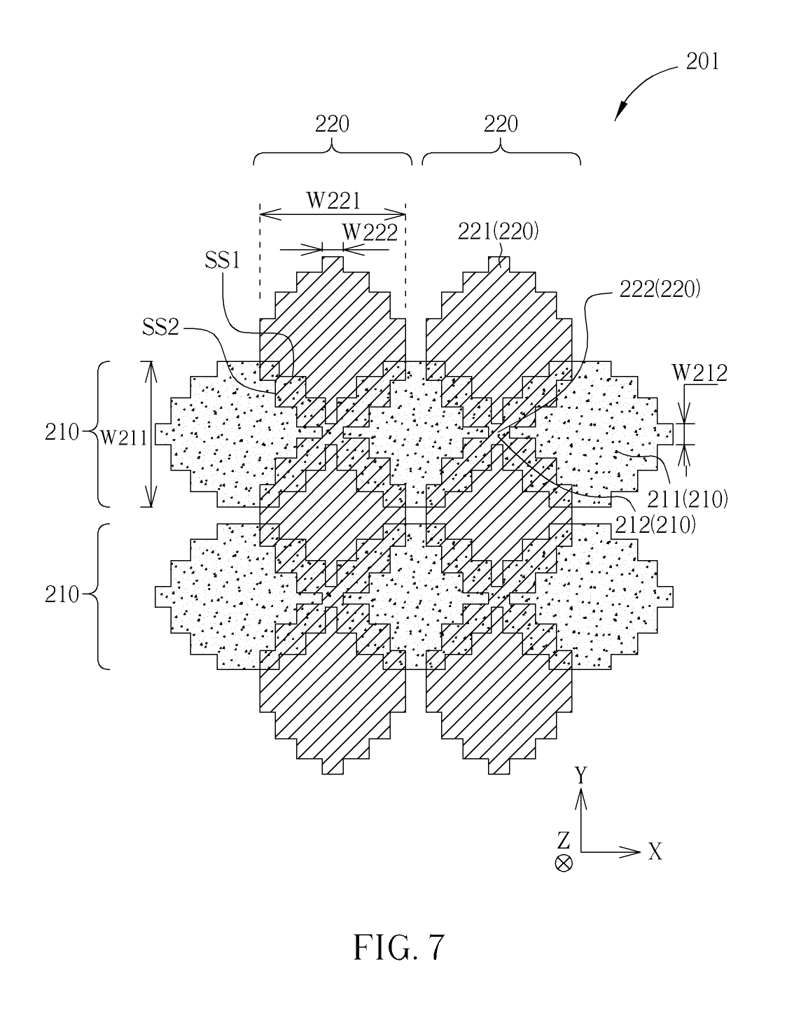

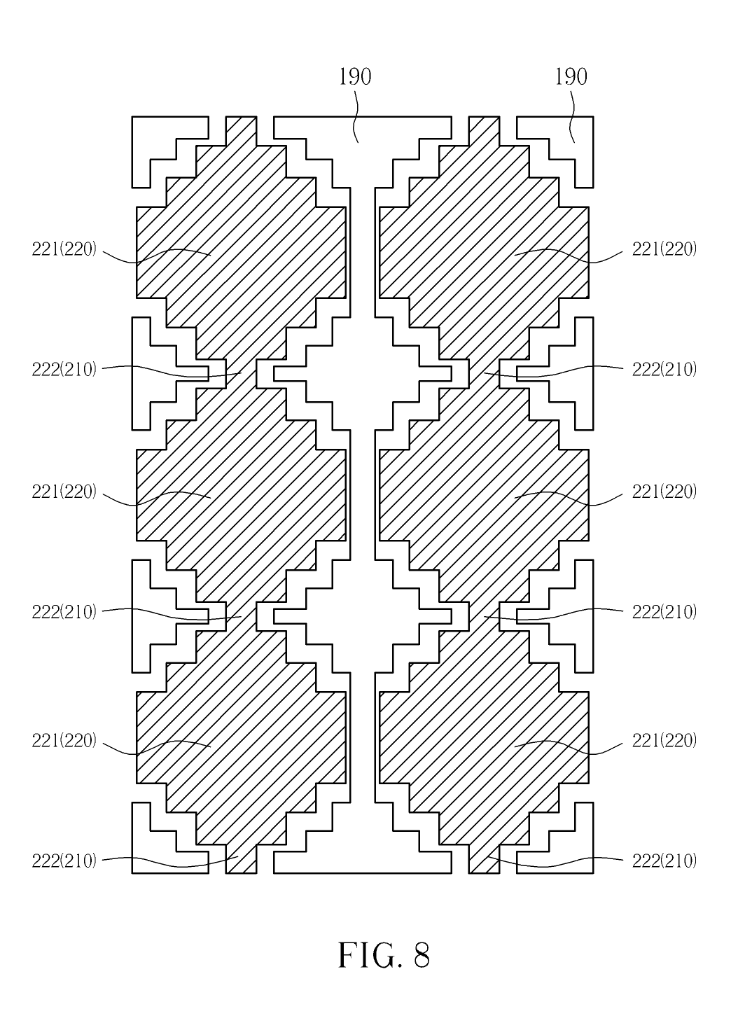

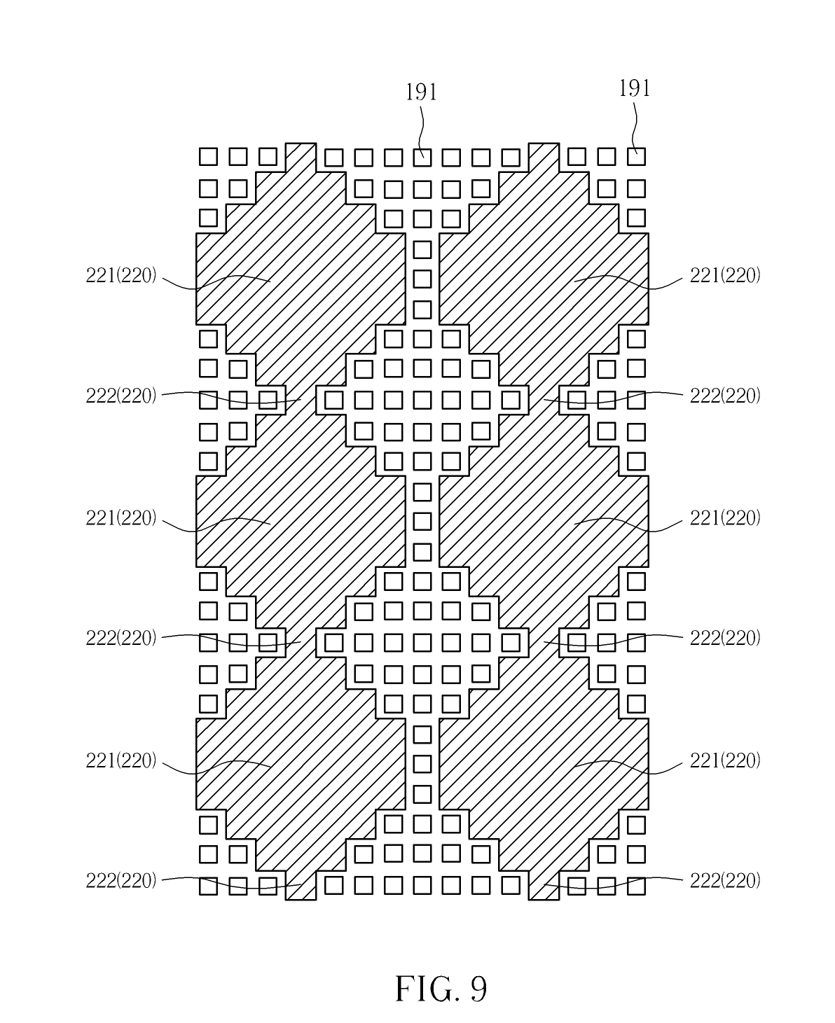

As shown in FIG. 7, FIG. 8 and FIG. 9, the capacitive touch panel 201 of this exemplary embodiment includes a plurality of first axis electrodes 210 and a plurality of second axis electrodes 220. Each of the first axis electrodes 210 extends along the first direction X. Each of the first axis electrodes 210 includes a plurality of first sensing electrodes 211 disposed along the first direction X and a plurality of first connecting electrodes 212 disposed respectively between two adjacent first sensing electrodes 211, and the first sensing electrodes 211 are electrically connected by the first connecting electrodes 212 in the same first axis electrode 210. Each of the second axis electrodes 220 extends along the second direction Y. Each of the second axis electrodes 220 includes a plurality of second sensing electrodes 221 disposed along the second direction Y and a plurality of second connecting electrodes 222 respectively disposed between two adjacent second sensing electrodes 221, and the second sensing electrodes 221 are electrically connected by the second connecting electrodes 222 in the same second axis electrode 120. Furthermore, a width W212 of each of the first connecting electrodes 212 is substantially smaller than a width W211 of each of the first sensing electrodes 211 along the second direction Y, a width W222 of each of the second connecting electrodes 222 is substantially smaller than a width W221 of each of the second sensing electrodes 221 along the first direction X, and each of the first sensing electrodes 211 partially overlaps the second sensing electrodes 221 along the third direction Z. It is appreciated that, in this exemplary embodiment, each of the first sensing electrodes 211 and each of the second sensing electrodes 221 respectively have a step-shaped side SS1 and a step-shaped side SS2. The illustrated step-shaped side design can maintain the sum of the regions wherein each of the first sensing electrodes 211 partially overlaps each of the second sensing electrodes 221 along the third direction Z without being affected by the shift of the relative position of each of the first axis electrodes 110 and each of the second axis electrodes 120. In other words, the sum of the regions wherein each of the first sensing electrodes 211 partially overlaps each of the second sensing electrodes 221 along the third direction Z may be kept at a fixed value due to the complementary effect, and will not be affected by the shift of the relative position of each of the first axis electrodes 210 and each of the second axis electrodes 220. Accordingly, the value of the vertical capacitance can be stabilized. The position shift status of this exemplary embodiment is similar to that of the first exemplary embodiment as shown in FIG. 3 through FIG. 5, and its description is omitted herein. Moreover, in this exemplary embodiment, the characteristics and the materials of the other components, the disposition of the first axis electrodes 210 and the second axis electrodes 220 on the substrate of the capacitive touch panel 201 are similar to the capacitive touch panel 101 and the capacitive touch panel 102 of the illustrated exemplary embodiments, except for the design of step-shaped side of the sensing electrodes, the similarities are therefore omitted herein for brevity.

It is appreciated that, as shown in FIG. 8, the capacitive touch panel 201 may further include a plurality of dummy electrodes 190 disposed between the second axis electrodes 220, i.e. the dummy electrodes 190 and the second axis electrodes 220 are disposed on the same surface, but not limited thereto. The material of the dummy electrodes 190 is preferably the same as the material of the second axis electrodes 220 in order to overcome the issue of non-uniform transmission of light caused by the overlapping region between the first sensing electrodes 211 and the second sensing electrodes 221. It is further appreciated that the capacitive touch panel 201 may further include a plurality of dummy electrodes (not shown) disposed between the first axis electrodes 210, i.e. the dummy electrodes and the first axis electrodes 210 are disposed on the same surface, but not limited thereto. Each of the dummy electrodes 190 is electrically insulated from the first axis electrodes 210 and the second axis electrodes 220. Through the deposition of dummy electrodes between the first axis electrodes 210 and/or between the second axis electrodes 220, the issue of non-uniform transmission of light can be overcome. Additionally, in this exemplary embodiment, the pattern of the dummy electrodes may be adjusted. For example, as shown in FIG. 9, a plurality of square-shaped dummy electrodes 191 is disposed between each of the second axis electrodes 220 to solve the non-uniform light transmission issue. It is noted that, in the exemplary embodiments as illustrated above, for example, the capacitive touch panel 101 and the capacitive touch panel 201 as shown in FIG. 1 may further include the dummy electrodes as well, in other words, the dummy electrodes 190 or the dummy electrodes 191 could be disposed between the first axis electrodes 110 or between the second axis electrodes 120 to solve the problem of non-uniform light transmission.

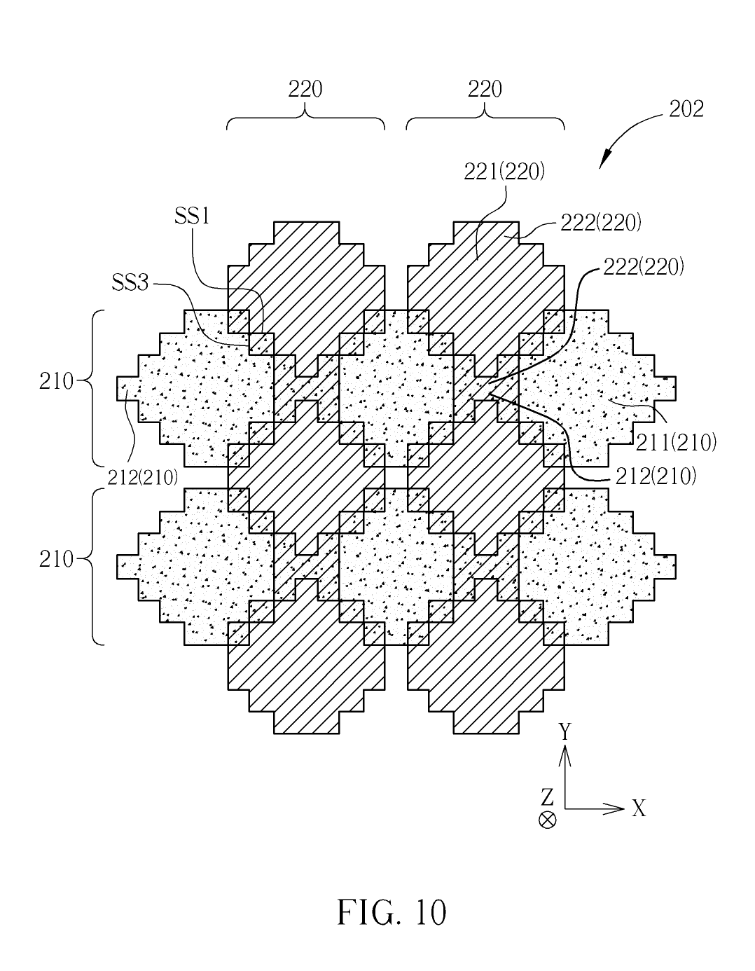

As shown in FIG. 10, in this exemplary embodiment, each of the second sensing electrodes 221 of the capacitive touch panel 202 has a step-shaped side SS3, and the number of steps of the step-shaped side SS3 is different from the number of steps of the step-shaped side SS2 in the illustrated capacitive touch panel 201. Accordingly, the vertical capacitance formed by the region wherein each of the first sensing electrodes 211 partially overlaps the second sensing electrodes 221 along the third direction Z in the capacitive touch panel 202 of this exemplary embodiment may be different from that of the capacitive touch panel 201 of the illustrated exemplary embodiment. In other words, in the present invention, the step shape of each of the sensing electrodes could be adjusted when the center position of each of the sensing electrodes is fixed, in order to modify the regions wherein each of the first sensing electrodes 211 partially overlaps the second sensing electrodes 221 to optimize the vertical capacitance as predetermined.

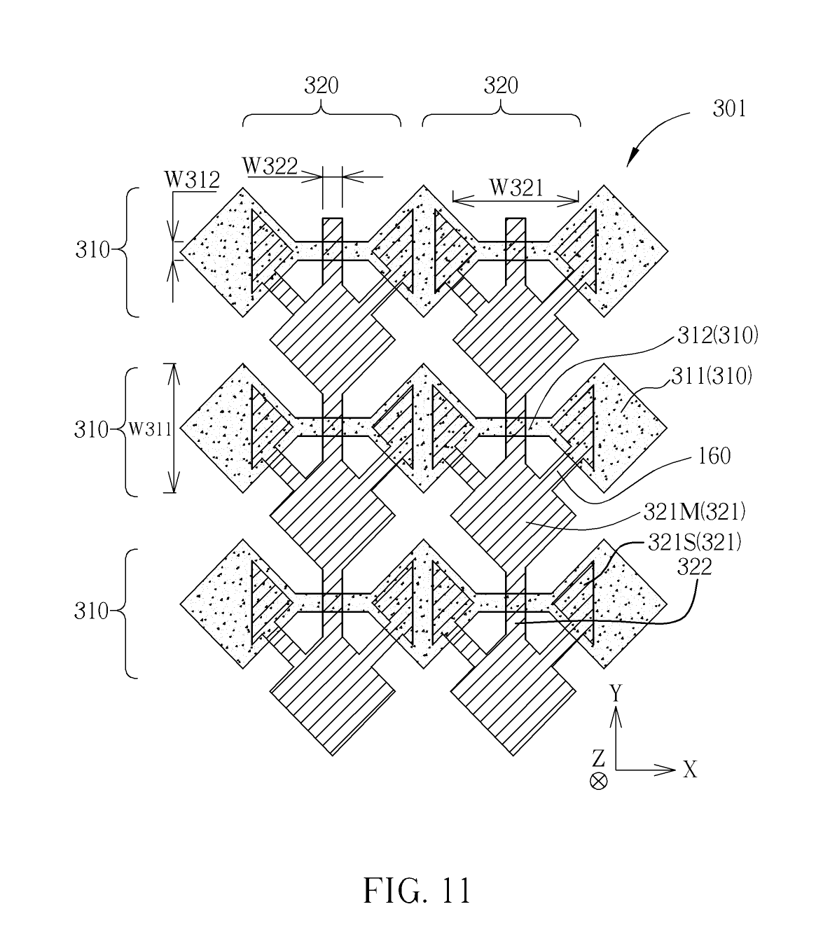

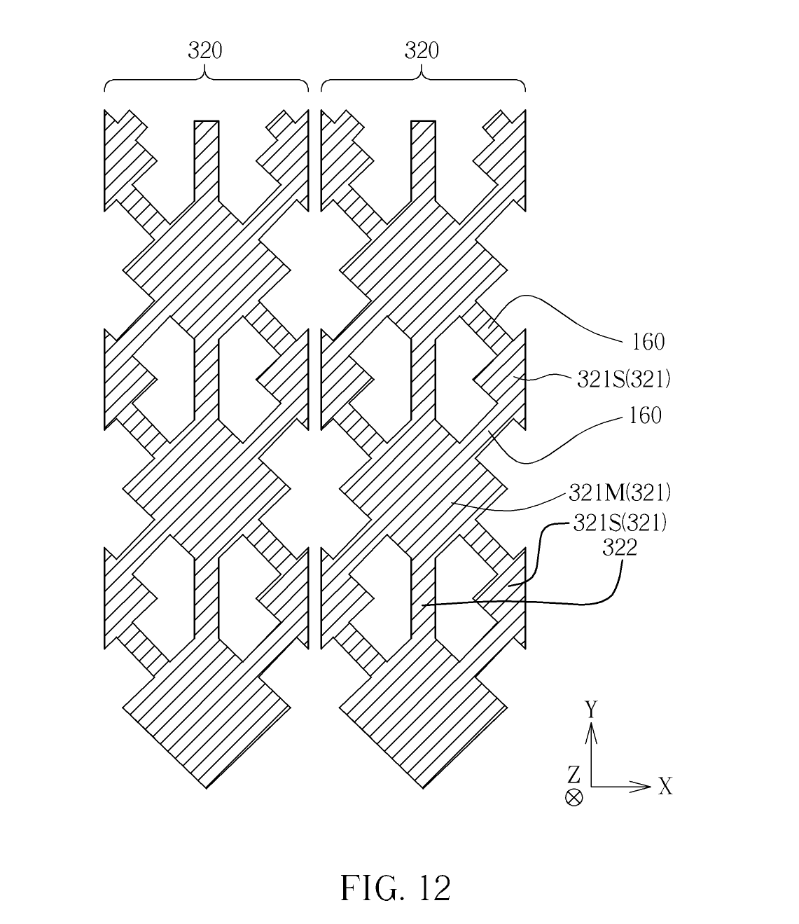

As shown in FIG. 11, FIG. 12 and FIG. 13, the capacitive touch panel 301 of this exemplary embodiment includes a plurality of first axis electrodes 310 and a plurality of second axis electrodes 320. Each of the first axis electrodes 310 extends along the first direction X. Each of the first axis electrodes 310 includes a plurality of first sensing electrodes 311 disposed along the first direction X and a plurality of first connecting electrodes 312 respectively disposed between two adjacent first sensing electrodes 311, and the first sensing electrodes 311 are electrically connected by the first connecting electrodes 312 in the same first axis electrode 310. Each of the second axis electrodes 320 extends along the second direction Y. Each of the second axis electrodes 320 includes a plurality of second sensing electrodes 321 disposed along the second direction Y and a plurality of second connecting electrodes 322 respectively disposed between two adjacent second sensing electrodes 321, and the second sensing electrodes 321 are electrically connected by the second connecting electrodes 322 in the same second axis electrode 320. Furthermore, a width W312 of each of the first connecting electrodes 312 is substantially smaller than a width W311 of each of the first sensing electrodes 311 along the second direction Y, a width W322 of each of the second connecting electrodes 322 is substantially smaller than a width W321 of each of the second sensing electrodes 321 along the first direction X, and each of the first sensing electrodes 311 partially overlaps the second sensing electrodes 321 along the third direction Z. It is appreciated that, in this exemplary embodiment, each of the second sensing electrodes 321 may include a main electrode 321M and a plurality of extending electrodes 321S, wherein each of the first sensing electrodes 311 at least partially overlaps the extending electrodes 321S along the third direction Z. Moreover, the capacitive touch panel 301 further includes a plurality of third connecting electrodes 160 disposed between the main electrode 321M and the extending electrode 321S, and each of the main electrodes 321M is electrically connected to each of the extending electrodes 321 S by the third connecting electrode 160. In this exemplary embodiment, an extending direction of each of the third connecting electrode 160 is preferably perpendicular to a side of the first sensing electrode 311.

The designs of the second sensing electrodes 321 and the third connecting electrodes 160 illustrated above can maintain the sum of the regions wherein each of the first sensing electrodes 311 partially overlaps the second sensing electrodes 321 along the third direction Z without being affected by the shift of the relative position of each of the first axis electrodes 310 and each of the second axis electrodes 320. In other words, the sum of the regions wherein each of the first sensing electrodes 311 partially overlaps the second sensing electrodes 321 along the third direction Z may be kept at a fixed value due to the complementary effect, and will therefore not be affected by the shift of the relative position of each of the first axis electrodes 310 and each of the second axis electrodes 320. Accordingly, the value of vertical capacitance can be stabilized. The position shift status of this exemplary embodiment is similar to that of the first exemplary embodiment as shown in FIG. 3 through FIG. 5, and omitted herein. Furthermore, the second sensing electrodes 321 and the third connecting electrodes 160 could be made of the same material to simplify the manufacturing process, but not limited thereto, the second sensing electrodes 321 and the third connecting electrodes 160 could be respectively made of different materials. In this exemplary embodiment, the characteristics and the materials of the other components, and the disposition of the first axis electrodes 310 and the second axis electrodes 320 on the substrate of the capacitive touch panel 301 are similar to the capacitive touch panel 101 and the capacitive touch panel 102 of the illustrated exemplary embodiments, except for the design of the second sensing electrodes 321 and the third connecting electrodes 160, therefore, the similarities are omitted herein for brevity.

It is appreciated that, as shown in FIG. 12, in an alternate embodiment of the fifth exemplary embodiment, each of the extending electrodes 321 S can be respectively electrically connected to two adjacent main electrodes 321M by the third connecting electrodes 160 in the same second axis electrode 320, in order to further reduce the overall resistance of each of the second axis electrode 320. Furthermore, as shown in FIG. 13, in another alternate embodiment of the fifth exemplary embodiment, each of the second axis electrodes 320 includes a plurality of second connecting electrodes 323, and each of the second connecting electrodes 323 is connected to one of the main electrodes 321M and one of the extending electrodes 321S. The design of the second connecting electrodes 323 may reduce the effect caused by the overlap between the second connecting electrodes 322 and the first connecting electrodes 312 along the third direction Z as shown in FIG. 11. It is further appreciated that, in the fifth exemplary embodiment, the capacitive touch panel 301 could further include a plurality of dummy electrodes (not shown, as the dummy electrodes 190 and the dummy electrodes 191 illustrated) disposed between the first axis electrodes 310, between the second axis electrodes 320 and between the main electrodes 321M, to solve the problem of non-uniform light transmission.

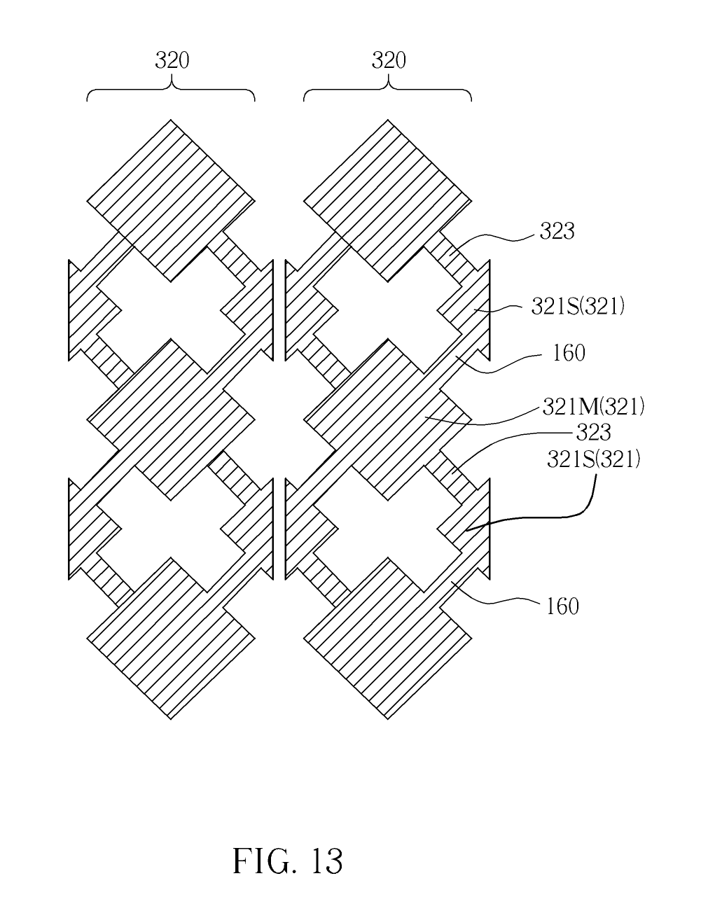

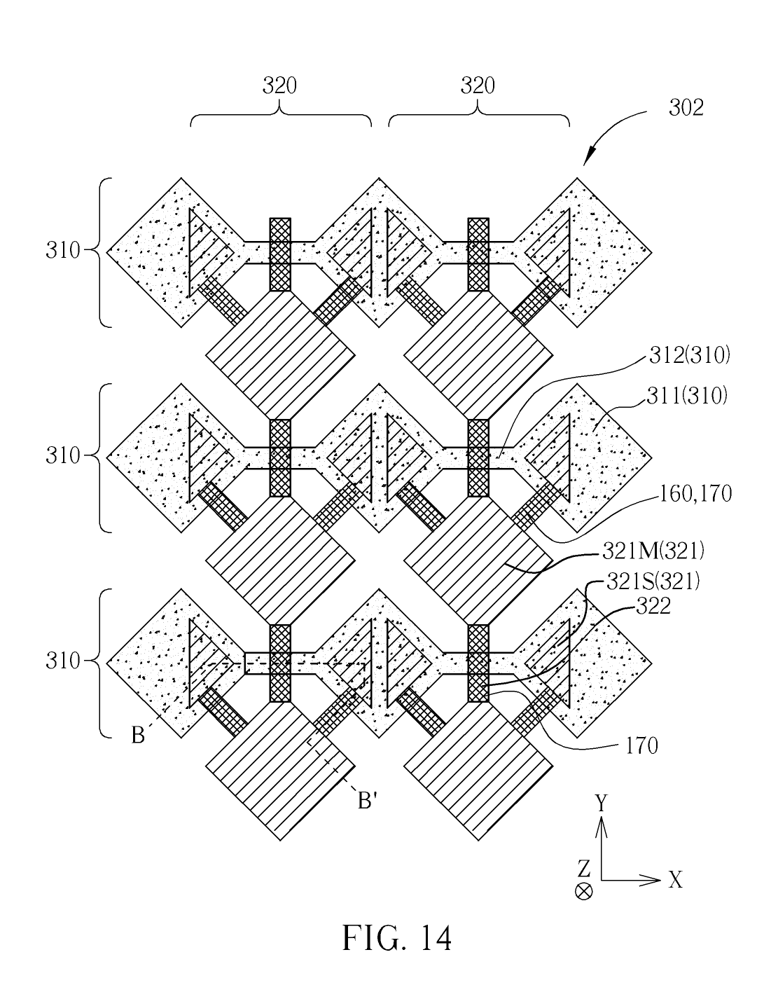

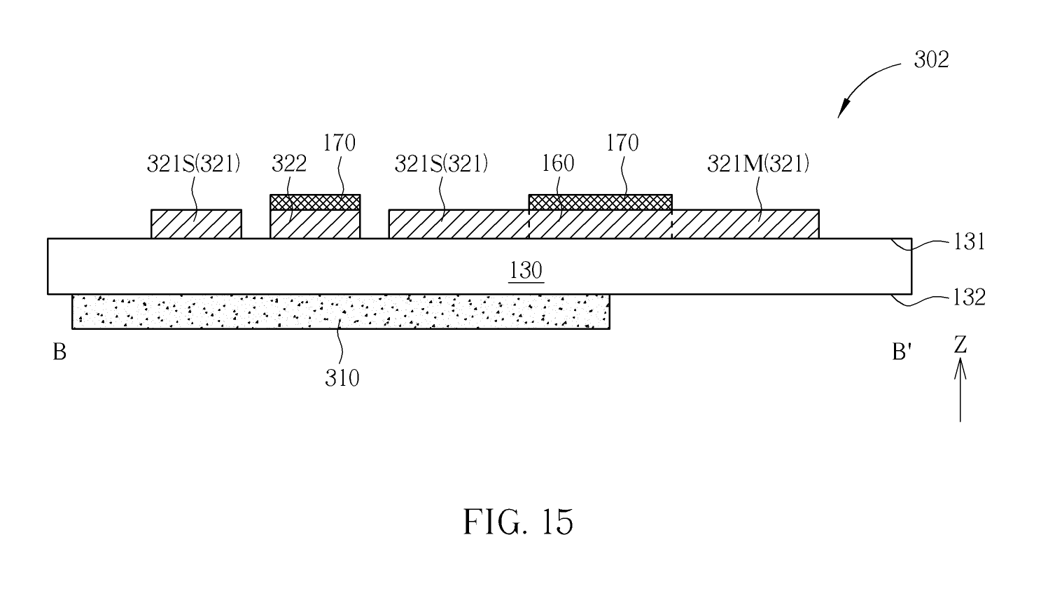

As shown in FIG. 14 and FIG. 15, compared to the capacitive touch panel 301, the capacitive touch panel 302 of this exemplary embodiment further includes a plurality of conductive covering patterns 170 electrically connected respectively to the second connecting electrodes 322 and the third connecting electrodes 160. Furthermore, a resistivity of the conductive covering pattern 170 is substantially smaller than a resistivity of the second connecting electrode 322 or a resistivity of the third connecting electrode 160, in order to reduce the overall resistance of each of the second axis electrode 320. The material of the conductive covering patterns 170 may include transparent conductive material such as indium tin oxide (ITO), indium zinc oxide (IZO) or aluminum zinc oxide (AZO), or opaque conductive materials such as silver (Ag), aluminum (Al), copper (Cu), magnesium (Mg), composite layers made of the illustrated materials, or alloys made of the illustrated materials, but not limited thereto. In this exemplary embodiment, the conductive covering patterns 170 may be directly disposed on each of the second connecting electrodes 322 and each of the third connecting electrodes 160, or electrically connected to two terminals of each of the second connecting electrodes 322 and two terminals of each of the third connecting electrodes 160 with the method of bridge to reduce the resistance. Moreover, the conductive covering patterns 170 could also be directly disposed on each of the first connecting electrodes 312 to reduce the overall resistance of each of the first axis electrode 310. The conductive covering patterns 170 are electrically connected to the first connecting electrodes 312, and a resistivity of the conductive covering patterns 170 is substantially smaller than a resistivity of the first connecting electrodes 312. In this exemplary embodiment, the characteristics and the materials of the other components of the capacitive touch panel 302 are the same as the capacitive touch panel 301 of the fifth exemplary embodiment, except for the disposition of the conductive covering patterns 170, and the similarities are therefore omitted herein for brevity.

In conclusion, in the capacitive touch panel of the present invention, the change of pattern design of each of the sensing electrodes can reduce the effect caused by the fluctuation of the overlapping region between the sensing electrodes along the vertical direction due to the process deviations. Furthermore, the region where each of the sensing electrodes overlaps each other can be modified according to demands without affecting the overall resistance of each of the axis electrode, and the vertical capacitance between the sensing electrodes can be effectively used to detect the touch point.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitive touch panel, comprising:
a substrate having a first surface and a second surface;
a plurality of first axis electrodes disposed on the substrate, and the first axis electrodes extending along a first direction, wherein each of the first axis electrodes comprises a plurality of first sensing electrodes disposed along the first direction and a plurality of first connecting electrodes respectively disposed between two adjacent first sensing electrodes, and the first sensing electrodes are electrically connected by the first connecting electrodes in the same first axis electrode; and
a plurality of second axis electrodes disposed on the substrate, and the second axis electrodes extending along a second direction, wherein each of the second axis electrodes comprises a plurality of second sensing electrodes disposed along the second direction and a plurality of second connecting electrodes respectively disposed between two adjacent second sensing electrodes, and the second sensing electrodes are electrically connected by the second connecting electrodes in the same second axis electrode,
wherein a width of each of the first connecting electrodes is substantially smaller than a width of each of the first sensing electrodes along the second direction, a width of each of the second connecting electrodes is substantially smaller than a width of each of the second sensing electrodes along the first direction, and each of the first sensing electrodes partially overlaps the second sensing electrodes along a third direction perpendicular to the substrate.

2. The capacitive touch panel according to claim 1, wherein at least one of each of the first sensing electrodes and each of the second sensing electrodes has a step-shaped side.

3. The capacitive touch panel according to claim 1, wherein each of the second sensing electrodes comprises a main electrode and a plurality of extending electrodes electrically connected to the main electrode, and each of the first sensing electrodes at least partially overlaps the extending electrodes along the third direction.

4. The capacitive touch panel according to claim 3, wherein at least one of the extending electrodes has an extending direction, and the extending direction is perpendicular to at least a side of at least one of each of the first sensing electrodes and each of the second sensing electrodes.

5. The capacitive touch panel according to claim 3, further comprising at least one third connecting electrode disposed between the main electrode and the extending electrode, wherein each of the main electrodes is electrically connected to each of the extending electrodes by the third connecting electrode.

6. The capacitive touch panel according to claim 5, wherein at least one of each of the first connecting electrodes and each of the second connecting electrodes is connected to one of the main electrodes and one of the extending electrodes.

7. The capacitive touch panel according to claim 5, further comprising a plurality of conductive covering patterns respectively electrically connected to at least one of the first connecting electrode, the second connecting electrode and the third connecting electrode, wherein a resistivity of the conductive covering pattern is substantially smaller than a resistivity of at least one of the first connecting electrode, the second connecting electrode and the third connecting electrode.

8. The capacitive touch panel according to claim 1, further comprising a plurality of dummy electrodes disposed between the first axis electrodes.

9. The capacitive touch panel according to claim 1, further comprising a plurality of dummy electrodes disposed between the second axis electrodes.

10. The capacitive touch panel according to claim 1, further comprising a dielectric layer disposed on the first surface of the substrate, wherein the first axis electrodes and the second axis electrodes are disposed on the first surface of the substrate, and the dielectric layer is disposed between the first axis electrode and the second axis electrode.

11. The capacitive touch panel according to claim 1, wherein the substrate is disposed between the first axis electrode and the second axis electrode.
